(19) United States
(12) Patent Application Publication
(10) Pub. No.: US 2012/0049897 A1
(43) Pub. Date: Mar. 1, 2012

(54) OUTPUT BUFFER CIRCUIT AND SEMICONDUCTOR DEVICE

(75) Inventor: Satoru KUBO, Kanagawa (JP)

(73) Assignee: Renesas Electronics Corporation

(21) Appl. No.: 13/173,803

(22) Filed: Jun. 30, 2011

(30) Foreign Application Priority Data
Aug. 26, 2010 (JP) 2010-189439

(51) Int. Cl. H03K 3/00

(52) U.S. Cl. 327/108

(57) ABSTRACT

In an output buffer circuit having a de-emphasis function, when the de-emphasis function is enabled, AC common-mode noise can occur which does not occur when the de-emphasis function is disabled. Besides, the de-emphasis can cause a reduction in de-emphasis strength. A current correction circuit is provided to correct currents supplied to two buffer circuits that provide the de-emphasis function, such that AC common-mode noise is suppressed and the reduction in the de-emphasis strength is prevented in a state in which the de-emphasis function is enabled.

### CROSS-REFERENCE TO RELATED APPLICATIONS

The disclosure of Japanese Patent Application No. 2010-189439 filed on Aug. 26, 2010 including the specification, drawings and abstract is incorporated herein by reference in its entirety.

### BACKGROUND

The present invention relates to the output buffer circuit and the semiconductor device. More particularly, the present invention relates to an output buffer circuit having a de-emphasis function by which an amplitude of output data is emphasized such that the amplitude is emphasized when a transition occurs in a logic of the output data but the amplitude is reduced when no transition occurs in the logic of the output data.

With rapid advances achieved in recent years in telecommunication technology, trunk transmission systems or server communication systems need an increasingly greater data transmission rate along longer transmission lines.

In semiconductor integrated circuits, to meet such a requirement, a high-speed interface macro is used to convert low-speed parallel signals into a high-speed serial signal and output resultant data. Such an interface macro is called a serializer/de-serializer macro and has a de-emphasis function to achieve high-speed and high-capacity communication along a long distance. The de-emphasis function refers to a function of emphasizing a waveform of an output signal such that the amplitude of output data is increased when a transition occurs in the logic of the output data by an amount depending on attenuation of communication data that can occur during transmission along a communication line, while the amplitude is reduced when no transition occurs in the logic of the output data.

The de-emphasis function can be achieved, for example, by a circuit configured as shown in FIG. 2. In this circuit, as shown in FIG. 2, communication data is input in the form of a differential signal. In a mode in which the de-emphasis function is enabled, a difference between the input data and data obtained by delaying the input data is detected to detect an occurrence of a transition in the logic of the input data, and the amplitude of the output signal is emphasized only immediately after the transition occurs in the logic of the signal thereby achieving the de-emphasis function.

Japanese Patent Application Publication No. 2007-060073 discloses a technique in which when the de-emphasis function is disabled, an output buffer for de-emphasis is used as an output buffer for main data thereby achieving overall optimization of a circuit, which allows a reduction in the total number of circuit elements and a reduction in power consumption.

### SUMMARY

The following discussion and analysis are provided for a better understanding of the present invention.

In an output buffer circuit shown in FIG. 2, in a mode in which the de-emphasis function is enabled, it is necessary to output a signal with a large emphasized amplitude immediately after a transition occurs in the logic of the signal. However, emphasizing of the amplitude can cause a large load to be applied to a current source circuit that supplies a current to the buffer circuit, and thus a reduction can occur in an output voltage or an output current supplied by the current source circuit, which makes it difficult to achieve a desired large amplitude for the output signal.

If the desired amplitude is not obtained for the output signal due to a reduction in the output current of the current source circuit, then this can cause a problem that AC common-mode noise occurs or a reduction in de-emphasis strength occurs. As will be discussed in further detail later, AC common-mode noise does not occur when the de-emphasis function is disabled, i.e., noise performance of the output buffer circuit is degraded only when the de-emphasis function is enabled. Furthermore, the reduction in the de-emphasis strength leads to a reduction in the transmission capacity of the output buffer circuit.

As described above, the related technique has problems to be solved.

In view of the above, it is desirable to provide an output buffer circuit and a semiconductor device using an output buffer circuit, capable of outputting a signal with a desired large emphasized amplitude in a mode in which the de-emphasis function is enabled without generating AC common-mode noise and without causing a reduction in de-emphasis strength.

According to a first aspect of the present invention, there is provided an output buffer circuit including a first buffer circuit configured to receive an input signal, a second buffer circuit configured to receive a signal produced by delaying the input signal and configured to be coupled to the same output terminal as that to which the first buffer circuit is coupled to, so as to output an output signal that is delayed and inversed in phase with respect to an output signal output by the first buffer circuit, and a current correction circuit configured to correct source currents flowing through the first and second buffer circuits when a transition occurs in the logic of the input signal.

According to a second aspect of the present invention, there is provided a semiconductor device including an output buffer circuit configured according to the first aspect.

The output buffer circuit according to the aspects of the present invention is capable of outputting a signal with a desired large emphasized amplitude in the mode in which the de-emphasis function is enabled. Because the reduction in the output amplitude is prevented, no AC common-mode noise occurs and no reduction in de-emphasis strength occurs.

### BRIEF DESCRIPTION OF THE DRAWINGS

FIG. 1 is a diagram illustrating an overview of the present invention.

FIG. 2 is a diagram illustrating an example of an output buffer circuit having a de-emphasis function.

FIG. 3 is a circuit diagram of a main buffer circuit shown in FIG. 2.

FIG. 4 is a diagram illustrating waveforms of signals associated with an operation of the output buffer circuit shown FIG. 2 in a de-emphasis-enabled state.

FIG. 5 is a timing chart illustrating an operation of the output buffer circuit shown in FIG. 2 in the de-emphasis-enabled state.

FIG. 6 is a timing chart illustrating an operation of the output buffer circuit shown in FIG. 2 in a de-emphasis-disabled state.

FIG. 7 is a block diagram illustrating an output buffer circuit according to a first embodiment of the present invention.

FIG. 8 is a circuit diagram of a main buffer circuit shown in FIG. 7.

FIG. 9 is a timing chart illustrating an operation of the output buffer circuit shown in FIG. 7 in the de-emphasis-enabled state.

FIG. 10 is a block diagram illustrating an output buffer circuit according to a second embodiment of the present invention.

FIG. 11 is a block diagram illustrating an output buffer circuit according to a third embodiment of the present invention.

FIG. 12 is a block diagram illustrating an output buffer circuit according to a fourth embodiment of the present invention.

FIG. 13 is a block diagram illustrating an output buffer circuit according to a fifth embodiment of the present invention.

FIG. 14 is a block diagram of an output buffer circuit configured to handle a single-ended signal.

FIG. 15 is a block diagram illustrating an output buffer circuit according to a sixth embodiment of the present invention.

FIG. 16 is a timing chart illustrating an operation in which no current correction is performed on in a mode in which a de-emphasis function for a single-ended signal is enabled.

FIG. 17 is a timing chart illustrating an operation of the output buffer circuit shown in FIG. 15 in the de-emphasis-enabled state.

### DETAILED DESCRIPTION

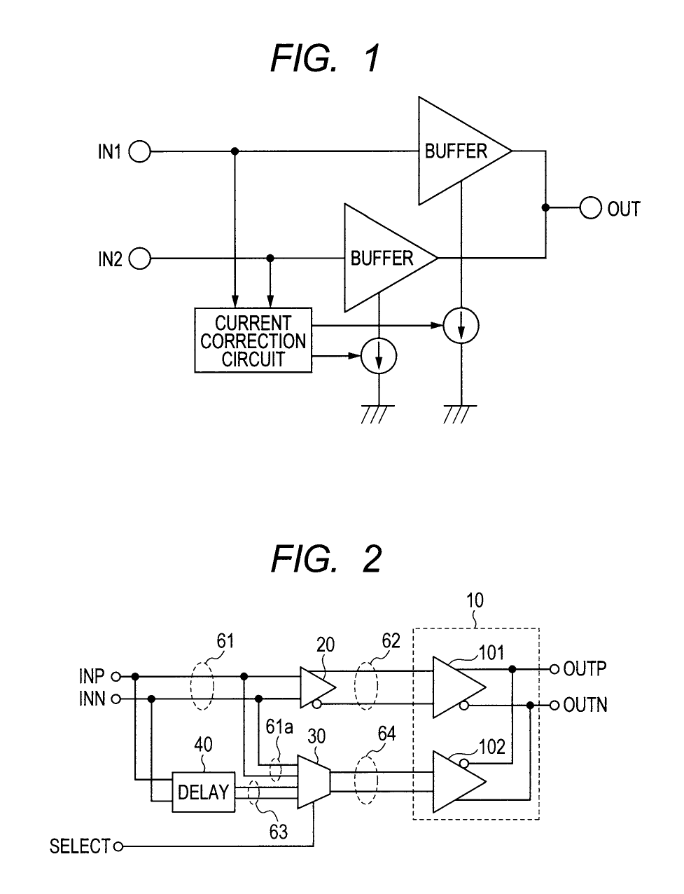

First, referring to FIG. 1, an overview of the present invention is given below. As described above, generation of AC common noise or a reduction in de-emphasis strength can occur when a signal with a large emphasized amplitude is output immediately after a transition occurs in the logic of the signal, because the emphasizing of the amplitude can cause a large load to be applied to a current source circuit that supplies a current to a buffer circuit, and thus a reduction can occur in an output current of the current source circuit. To prevent such a reduction in current, a current correction circuit is provided for correcting currents supplied to two buffer circuits by adjusting current sources coupled to the respective two buffers during a period immediately after a transition occurs in the logic of the signal (hereafter, such a period will be referred to as a transition bit period). The provision of the correction circuit makes it possible to suppress AC common-mode noise and prevent the reduction in the de-emphasis strength in the transition bit period.

Before a description is provided as to embodiments of the present invention, a basic circuit configuration of an output buffer circuit having a de-emphasis function is described below with reference to FIG. 2. FIG. 2 illustrates an example of an output buffer circuit having the de-emphasis function. The output buffer circuit shown in FIG. 2 includes a main buffer 10, a pre-buffer 20 for main data, a selection circuit 30, and a delay circuit 40. The main buffer 10 includes a main buffer 101 for main data and a main buffer 102 for de-emphasis.

Input data to the output buffer circuit is given in the form of a differential signal (differential signal 61) from a non-inverting input terminal INP of the output buffer circuit and an inverting input terminal INN of the output buffer circuit. The pre-buffer 20 for main data receives the differential signal 61 as an input signal thereto, amplifies the differential signal 61, and outputs a resultant differential signal as a differential signal 62.

The selection circuit 30 receives a differential signal 61a and a differential signal 63 as input signals applied thereto, where the differential signal 61a is a signal that is inverse in phase to the differential signal 61 and that is obtained by interchanging (crossing) the non-inverting signal and the inverting signal of the differential signal 61. Furthermore, an output signal of a de-emphasis setting terminal SELECT is given as a selection signal to the selection circuit 30. The selection circuit 30 selects either the differential signal 61a that is inversed to the differential signal 61 or the differential signal 63 depending on the logic of the de-emphasis setting terminal SELECT. The selected signal is output as a differential signal 64.

The delay circuit 40 receives the differential signal 61 as an input signal thereto and outputs the differential signal 63 produced by delaying the differential signal 61.

The main buffer 101 for main data receives the differential signal 62 as an input signal thereto and outputs a differential signal produced by amplifying the differential signal 62 at a non-inverting output terminal OUTP and an inverting output terminal OUTN of the output buffer circuit.

The main buffer 102 for de-emphasis receives the differential signal 64 as an input signal thereto and outputs a differential signal produced by amplifying the differential signal 64 at the non-inverting output terminal OUTP and the inverting output terminal OUTN of the output buffer circuit. Note that the output terminals of the main buffer 102 for de-emphasis are coupled to the output terminals of the output buffer circuit such that the non-inverting output signal is coupled to the inverting output terminal OUTN of the output buffer circuit and the inverting output signal is coupled to the non-inverting output terminal OUTP of the output buffer circuit.

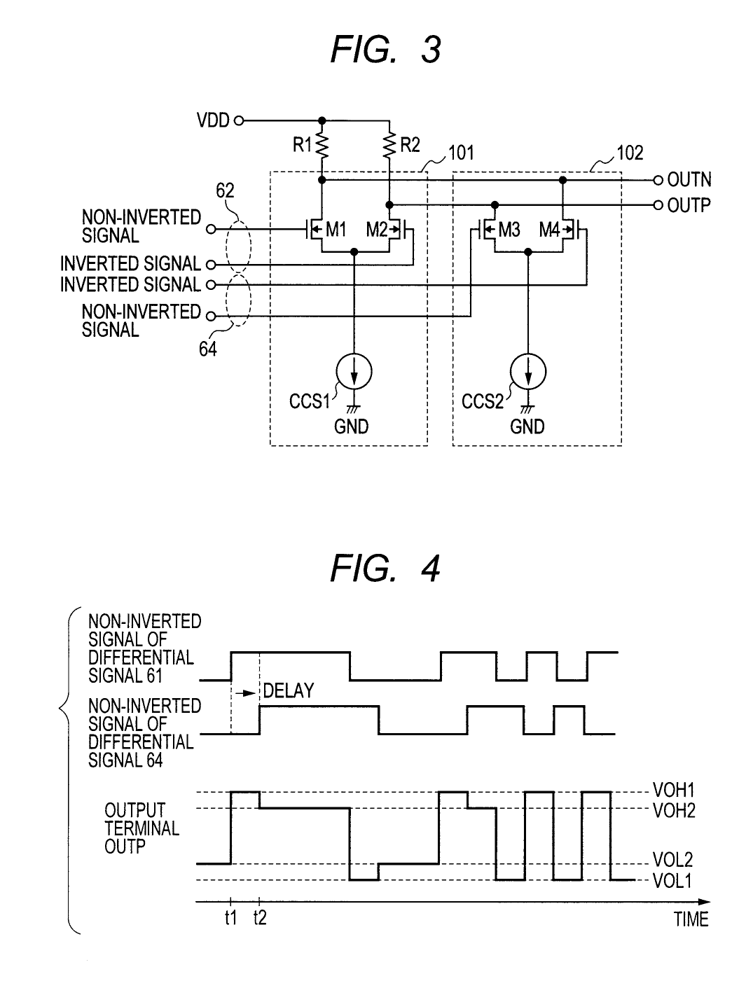

FIG. 3 is a circuit diagram illustrating an example of a configuration of the main buffer 10 shown in FIG. 2. The main buffer 101 for main data includes N-channel transistors M1 and M2 and a constant current source CCS1. The main buffer 102 for de-emphasis includes N-channel transistors M3 and M4 and a constant current source CCS2.

In the main buffer 101 for main data, source terminals of the N-channel transistors M1 and M2 are coupled together to the constant current source CCS1. The non-inverting signal of the differential signal 62 is coupled to a gate terminal of the N-channel transistor Ml, and the inverting signal of the differential signal 62 is coupled to a gate terminal of the N-channel transistor M2. Furthermore, drain terminals of the N-channel transistors M1 and M2 are coupled to a power supply VDD via respective resistors R1 and R2.

In the main buffer 102 for de-emphasis, source terminals of the N-channel transistors M3 and M4 are coupled together to the constant current source CCS2. The non-inverting signal of the differential signal 64 is coupled to a gate terminal of the N-channel transistor M3, and the inverting signal of the differential signal 64 is coupled to a gate terminal of the N-channel transistor M4. Furthermore, drain terminals of the N-channel transistors M3 and M4 are respectively coupled to the drain terminals of the N-channel transistors M1 and M2 such that they are respectively coupled in common to the power supply VDD via the respective resistors R1 and R2.

Next, a basic operation of the output buffer circuit configured in the above-described manner is described below. In this output buffer circuit, when the de-emphasis setting terminal SELECT is set at an H (high) level, the de-emphasis function is enabled. On the other hand, when the de-emphasis setting terminal SELECT is set at an L (low) level, the de-emphasis function is disabled.

In a state in which the de-emphasis function is set to be enabled, the main buffer 10 subtracts the differential signal 63 delayed by the delay circuit 40 from the differential signal 62 thereby obtaining a signal with a large emphasized amplitude when a transition occurs in the logic of the signal.

On the other hand, in the de-emphasis-disabled state, the main buffer 10 performs subtraction between the differential signal 61 and the differential signal 61a that is opposite in phase to the differential signal 61 and outputs the result. In this case, because the subtraction is performed between the differential signal and its crossed signal, the result is equivalent to the addition of two identical differential signals 61.

In the de-emphasis-enabled state, although the emphasis of amplitude is performed for a transition bit, i.e., a first bit after a transition occurs in the logic of the signal output from the main buffer (from terminals OUTP and OUTN), the amplitude is reduced for bits (non-transition bits) that follow the transition bit and that are equal in logic to the transition bit.

Next, referring to FIGS. 4 to 6, the operation in the de-emphasis-enabled mode is described in further detail below. In the following description, it is assumed that the HIGH level is logic 1 and the LOW level is logic 0. FIG. 4 illustrates a relationship among the differential signal 61, the non-inverting signal of the differential signal 64, and the signal at the output terminal OUTP in the de-emphasis-enabled mode.

First, a discussion is given below as to an operation in which the differential signal 62 changes from a state in which the non-inverting signal of the differential signal 62 is at a 0-level (while the inverting signal of the differential signal 62 is at a 1-level) to a state in which the non-inverting signal of the differential signal 62 is at the 1-level (while the inverting signal of the differential signal 62 is at the 0-level). At this transition, the non-inverting signal of the differential signal 64 output from the selection circuit 30 is at the 0-level (at time t1 in FIG. 4). As a result of the transition, the N-channel transistors M1 and M4 whose drain terminals are coupled together turn on, and the N-channel transistors M2 and M3 turn off. As a result, a current equal to the sum of a current I1 supplied from the constant current source CCS1 and a current I2 supplied from the constant current source CCS2 flows through the resistor R1. On the other hand, no current flows through the resistor R2.

In this state, the voltage at the output terminals (OUTN and OUTP) can be calculated as follows.

OUTN=VDD−(I1+I2)×R1

OUTP=VDD

Thus, the amplitude given by the difference between OUTP and OUTN becomes as follows.

OUTP−OUTN=(I1+I2)×R1

Next, a discussion is given below as to a state in which the non-inverting signal of the differential signal 62 is at the 1-level (while the inverting signal of the differential signal 62 is at the 0-level) and the non-inverting signal of the differential signal 64 is at the 1-level (while the inverting signal of the differential signal 64 is at the 0-level) (at time t2 in FIG. 4). In this state, the N-channel transistors M1 and M3 turn on, and N-channel transistors M2 and M4 turn off. As a result, the current I1 supplied from the constant current source CCS1 flows through the resistor R1, and the current I2 supplied from the constant current source CCS2 flows through the resistor R2.

In this state, the respective output terminals have the following voltages.

OUTN=VDD−R1×I1

OUTP=VDD−R2×I2

Thus, the amplitude has the following value.

OUTP−OUTN=R1×I1−R2×I2

If R1=R2=R, then OUTP−OUTN=R×(I1−I2). From the above discussion, it can be seen that when a change occurs in data of the differential signal 62, the amplitude has a large value immediately after the change while the amplitude is small when there is no change in data. Thus, de-emphasis is achieved.

As described above, the output buffer circuit shown in FIG. 2 emphasizes each transition bit thereby achieving the de-emphasis function. However, the output buffer circuit shown in FIG. 2 has a problem that the low-level voltage does not drop to a designed value during the transition bit period.

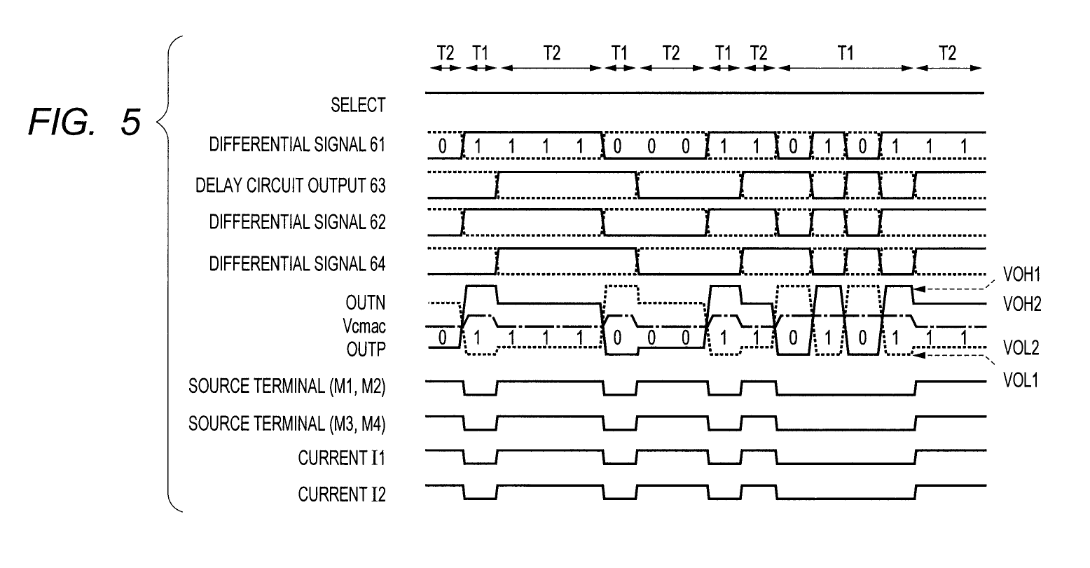

Next, referring to a timing chart shown in FIG. 5, a reason is discussed below as to why the low-level voltage does not drop to the designed value during the transition bit period. The timing chart of FIG. 5 illustrates an operation of the circuit shown in FIG. 2 in the de-emphasis-enabled state. In FIG. 5, a horizontal axis represents a time, and a vertical axis represents a voltage or a current. Each period T1 is a transition bit period, and each period T2 is a non-transition bit period. The SELECT signal, the differential signal 61, the differential signal 63 output by the delay circuit 40, the differential signal 62, the differential signal 64, the inverting output OUTN of the output buffer circuit, the non-inverting output OUTP of the output buffer circuit, the voltages at the source terminals of the N-channel transistors M1 to M4, and the currents I1 and I2 supplied from the constant current sources CCS1 and CCS2 are plotted in the vertical axis such that they are shifted in the vertical direction so that no overlapping occurs. Note that in FIG. 5, non-inverting signals of differential signals are represented by solid lines, while inverting signals are represented by dotted lines.

VOH1 denotes a high voltage level in the transition bit period, VOL1 denotes a low voltage level in the transition bit period, VOH2 denotes a high voltage level in the non-transition bit period, and VOL2 denotes a low voltage level in the non-transition bit period. Vcmac denotes a voltage level of an AC common-mode voltage.

First, an operation in a transition-bit state during the period T1 (transition bit period) is described.

During the period T1, the operation is in the transition-bit state immediately after a transition of the transmission data from the 0-level to the 1-level or from the 1-level to the 0-level. In this state, the voltage amplitude of the non-inverting output terminal OUTP of the output buffer circuit and the voltage amplitude of the inverting output terminal OUTN of the output buffer circuit are greater than those during the period T2 (non-transition bit period) and thus a change in the signal is emphasized. That is, the output voltage of the non-inverting output terminal OUTP of the output buffer circuit is at a high logic output level VOH1, and the output voltage of the inverting output terminal OUTN of the output buffer circuit is at a low logic output level VOL1.

On the other hand, although not shown, each of the N-channel transistors M1 to M4 has a drain-source resistance Rds depending on the drain-source voltage Vds. Via the drain-source resistance Rds of each N-channel transistor, drain signals of the N-channel transistors M1 and M2 can propagate to the common source thereof, which can create influences as described below.

In particular, when the drain signal is at the low logic output level VOL1, the drain-source resistance Rds is smaller than when the drain signal is at the high logic output level VOH1, and thus the drain voltage can more easily propagate to the source, i.e., the drain voltage has a greater influence.

In general, the constant current sources CCS1 and CCS2 are each realized by an N-channel transistor. The source of each of the N-channel transistors M1 and M2 is coupled to the drain of the N-channel transistor functioning as the constant current source CCS1, and the source of each of the N-channel transistors M3 and M4 is coupled to the drain of the N-channel transistor functioning as the constant current source CCS2, and thus a reduction occurs in the drain voltage of each of the N-channel transistors functioning as the constant current sources CCS1 and CCS2. This leads to a reduction in drain-source voltage Vds of the N-channel transistors functioning as the constant current sources. As a result, the constant currents I1 and I2 flowing through the constant current sources CCS1 and CCS2 decrease, which causes the low logic voltage level given by VDD−(I1+I2)×R1 not to drop to as low a level as VOL1. That is, the low logic output level of the non-inverting output terminal OUTP of the output buffer circuit and the low logic output level of the inverting output terminal OUTN of the output buffer circuit cannot drop to as low a level as VOL1. As a result, in the state in which the de-emphasis is enabled, AC common-mode noise can occur during the transition bit period.

Next, AC common-mode noise that can occur in the de-emphasis-enabled state is described below. The AC common-mode noise is noise that occurs between a transmission signal and the ground, which can cause unnecessary noise to radiate from a transmission line. The AC common-mode noise Vcmac can be calculated according to equation (1) shown below.

Vcmac=(OUTP+OUTN)/2 (1)

From equation (1), it can be seen that AC common-mode noise does not occur if the non-inverting output terminal OUTP of the output buffer circuit and the inverting output terminal OUTN of the output buffer circuit are compliment to each other.

For example, when the high logic output level of the non-inverting output terminal OUTP of the output buffer circuit is 1 V and the low logic output level of the inverting output terminal OUTN of the output buffer circuit is −0.8 V, the AC common-mode noise can be calculated as Vcmac=0.1 V according to equation (1). As can be seen from the above discussion, if the low logic output level of the non-inverting output terminal OUTP of the output buffer circuit and the low logic output level of the inverting output terminal OUTN of the output buffer circuit do not decrease to as low a level as VOL1, AC common-mode noise can occur in the output buffer circuit shown in FIG. 2.

Next, an operation in a non-transition bit state during the period T2 (non-transition bit period) is described.

During the period T2, the operation is in the non-transition bit state in which communication data has successive 0s or 1s. In this period T2, the voltage amplitude of the non-inverting output terminal OUTP of the output buffer circuit and the voltage amplitude of the inverting output terminal OUTN of the output buffer circuit are smaller than during the period T1 (in the transition bit state) and no emphasis is performed on signals. More specifically, in this state, the output voltage level of the non-inverting output terminal OUTP of the output buffer circuit is the high logic output level VOH2, while the output voltage level of the inverting output terminal OUTN of the output buffer circuit is the low logic output level VOL2.

The low logic output level VOL2 propagates to the sources of the N-channel transistors M1 to M4 and influences them, as during the period T1. However, VOL2 is higher than the low logic output level VOL1, and thus VOL2 does not lead to a reduction in the output voltages of the constant current sources CCS1 and CCS2, and thus does not lead to a reduction in the currents I1 and I2 flowing through the constant current sources CCS1 and CCS2. Therefore, the low logic output level of the non-inverting output terminal OUTP of the output buffer circuit and the low logic output level of the inverting output terminal OUTN of the output buffer circuit drop to as low a level as VOL2, and thus AC common-mode noise Vcmac does not occur as can be seen from equation (1) (having a normal center value).

More specifically, for example, when the high logic output level is 0.5 V and the low logic output level is −0.5 V, AC common-mode noise can be calculated as Vcmac=0 V according to equation (1).

In the output buffer circuit, as described above, when the de-emphasis is enabled, AC common-mode noise Vcmac can occur during the transition bit period T1.

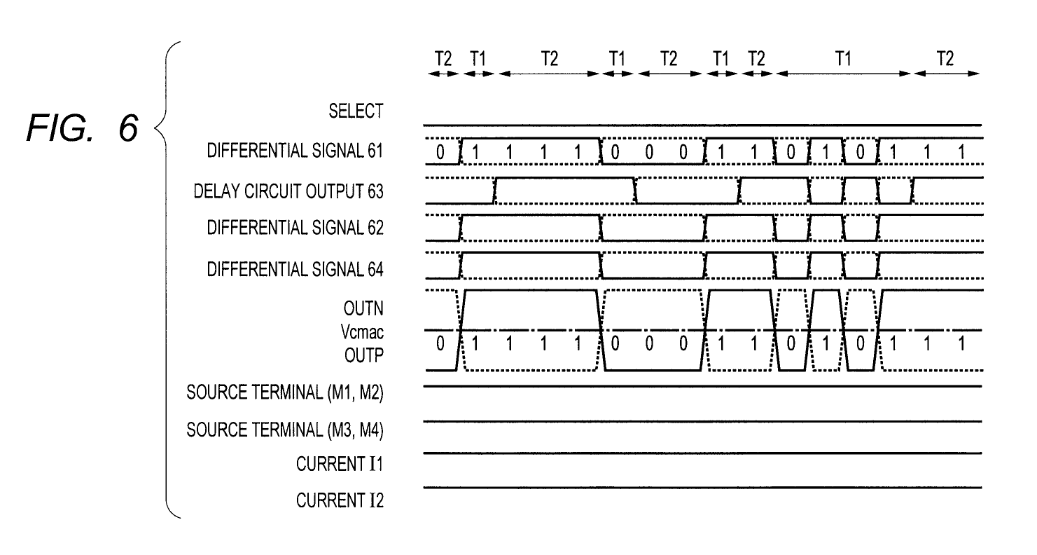

FIG. 6 is a timing chart illustrating an operation of the output buffer circuit shown in FIG. 2 in the state in which the de-emphasis is disabled. As can be seen from FIG. 6, no AC common-mode noise occurs in the de-emphasis-disabled state.

In the transition bit period, if the low voltage does not drop to a designed level, then the result is a problem that a reduction occurs in the de-emphasis strength given by the ratio of the voltage amplitude in the transition bit period and that in the non-transition bit period. The de-emphasis strength can be calculated according to the following equation (2):

20 log((voltage amplitude in the period T1)/(voltage amplitude in the period T2)) (2)

That is, in the transition bit period, if the low voltage does not drop to VOL1, then the result is a reduction in the voltage amplitude in the period T1, and thus a reduction occurs in the de-emphasis strength given by equation (2).

### First Embodiment

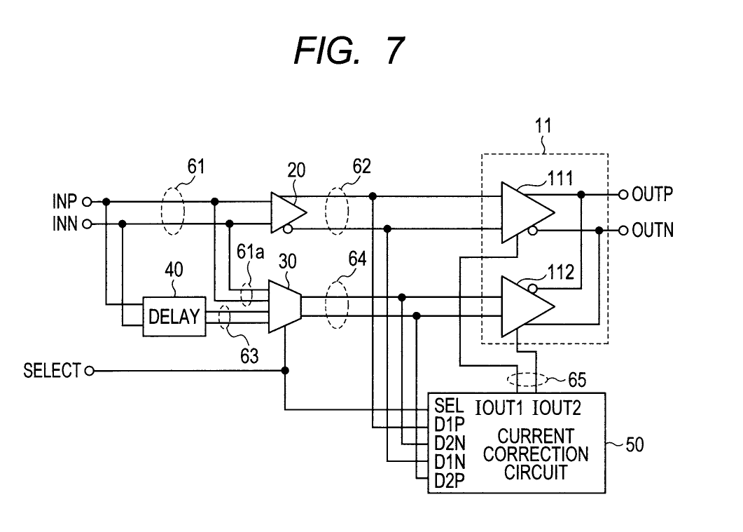

An output buffer circuit according to a first embodiment of the present invention is described in detail below with reference to drawings. FIG. 7 is a block diagram illustrating a configuration of the output buffer circuit according to the first embodiment. In FIG. 7, similar elements to those in FIG. 2 are denoted by similar reference numerals and an explanation thereof is omitted.

The output buffer circuit according to the present embodiment is different from the output buffer circuit shown in FIG. 2 in that a current correction circuit 50 is additionally provided. The current correction circuit 50 is configured to correct a current flowing through a source terminal of an N-channel transistor in a de-emphasis-enabled state.

Signals are coupled to the current correction circuit 50 as follows. A non-inverting signal of a differential signal 62 is coupled to a non-inverting input terminal D1P of main data, while an inverting signal of the differential signal 62 is coupled to an inverting input terminal DIN of the main data. A non-inverting signal of a differential signal 64 is coupled to a non-inverting input terminal D2P of de-emphasis data, while an inverting signal of the differential signal 64 is coupled to an inverting input terminal D2N of the de-emphasis data. A de-emphasis setting terminal SELECT is coupled to a control circuit setting terminal SEL. The current correction circuit 50 includes additional two terminals functioning as output terminals. A correction current output terminal IOUT1 is coupled to a main buffer 111 for main data, and a correction current output terminal IOUT2 is coupled to a main buffer 112 for de-emphasis. A correction current 65 is output from the correction current output terminals IOUT1 and IOUT2.

As described above, the main buffer 111 for main data is coupled to the terminal IOUT1 in addition to the differential signal 62 such that the correction current 65 is input from the terminal IOUT1. Similarly, the main buffer 112 for de-emphasis is coupled to the terminal IOUT2 in addition to the differential signal 64 such that the correction current 65 is input from the terminal IOUT2.

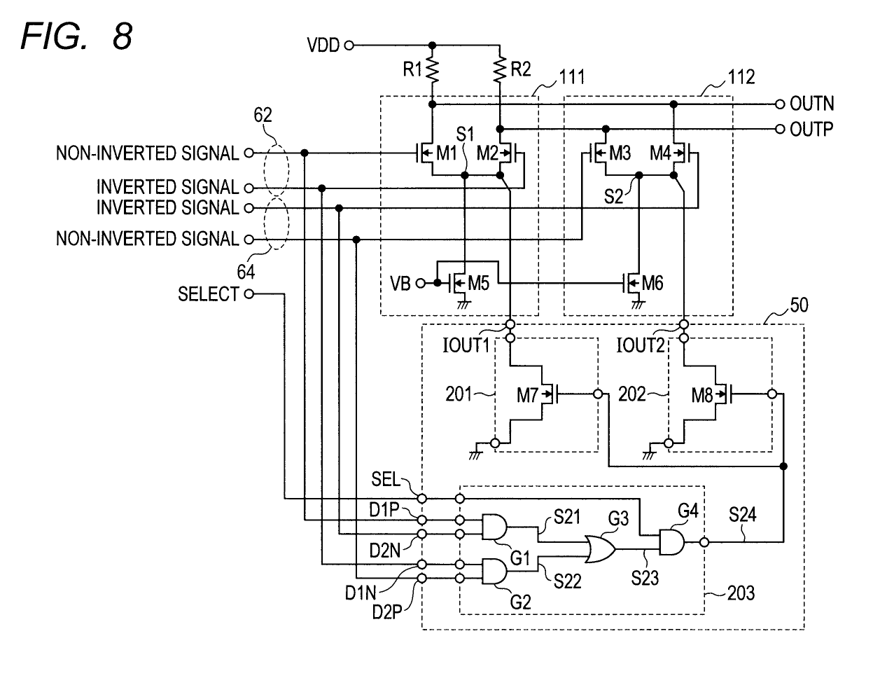

FIG. 8 is a circuit diagram of the output buffer circuit according to the present embodiment of the invention. The output buffer circuit according to the present embodiment includes a main buffer 11 and the current correction circuit 50.

The main buffer 111 for main data includes resistors R1 and R2 and N-channel transistors M1, M2, and M5. The main buffer 112 for de-emphasis includes the resistors R1 and R2 shared with the main buffer 111 for main data and N-channel transistors M3, M4, and M6.

The non-inverting signal of the differential signal 62 is coupled to a gate terminal of the N-channel transistor M1 and the main data non-inverting input terminal D1P of the current correction circuit 50. The inverting signal of the differential signal 62 is coupled to a gate terminal of the N-channel transistor M2 and the main data inverting input terminal D1N of the current correction circuit 50. Similarly, the non-inverting signal of the differential signal 64 is coupled to a gate terminal of the N-channel transistor M3 and the de-emphasis data non-inverting input terminal D2P of the current correction circuit 50. The inverting signal of the differential signal 64 a gate terminal of the N-channel transistor M4 and the de-emphasis data inverting input terminal D2N of the current correction circuit 50.

Source terminals of the N-channel transistors M1 and M2 are coupled together to a drain terminal of the N-channel transistor M5 and the correction current output terminal IOUT1. Similarly, source terminals of the N-channel transistors M3 and M4 are coupled together to a drain terminal of the N-channel transistor M6 and the correction current output terminal IOUT2. Gate terminals of the N-channel transistors M5 and M6 are coupled together to a bias terminal VB, while source terminals thereof are coupled to the ground. The N-channel transistor M5 functions as a current source that provides a current to a differential pair of the main buffer 111 for main data including the N-channel transistors M1 and M2. Similarly, the N-channel transistor M6 functions as a current source that provides a current to a differential pair of the main buffer 112 for de-emphasis including the N-channel transistors M3 and M4. The main buffer 111 for main data and the main buffer 112 for de-emphasis have been described above in detail.

Next, the current correction circuit 50 is described below. The current correction circuit 50 includes a switch 201, a switch 202, and a control circuit 203.

In an embodiment, by way of example, the switches 201 and 202 in the current correction circuit 50 are realized by N-channel transistors M7 and M8, respectively, and the control circuit 203 is configured using logic circuits G1 to G4.

The N-channel transistor M7 functioning as the switch 201 is coupled such that a drain terminal is coupled to the correction current output terminal IOUT1, a gate terminal is coupled to an output of the logic circuit G4, and a source terminal is coupled to the ground. The N-channel transistor M8 functioning as the switch 202 is coupled in a similar manner.

In the control circuit 203, an input of the AND logic circuit G1 is coupled to a main data non-inverting input terminal D1P, while the other input thereof is coupled to a de-emphasis data inverting input terminal D2N. An output of the AND logic circuit G1 is coupled to an input of the OR logic circuit G3.

An input of the AND logic circuit G2 is coupled to the main data inverting input terminal D1N, while the other input thereof is coupled to the de-emphasis data non-inverting input terminal D2P. An output of the AND logic circuit G2 is coupled to an input, different from the input to which the output of the AND logic circuit G1 is coupled, of the OR logic circuit G3. An output of the OR logic circuit G3 is input to the AND logic circuit G4. The other input of the AND logic circuit G4 is coupled to the control circuit setting terminal SEL.

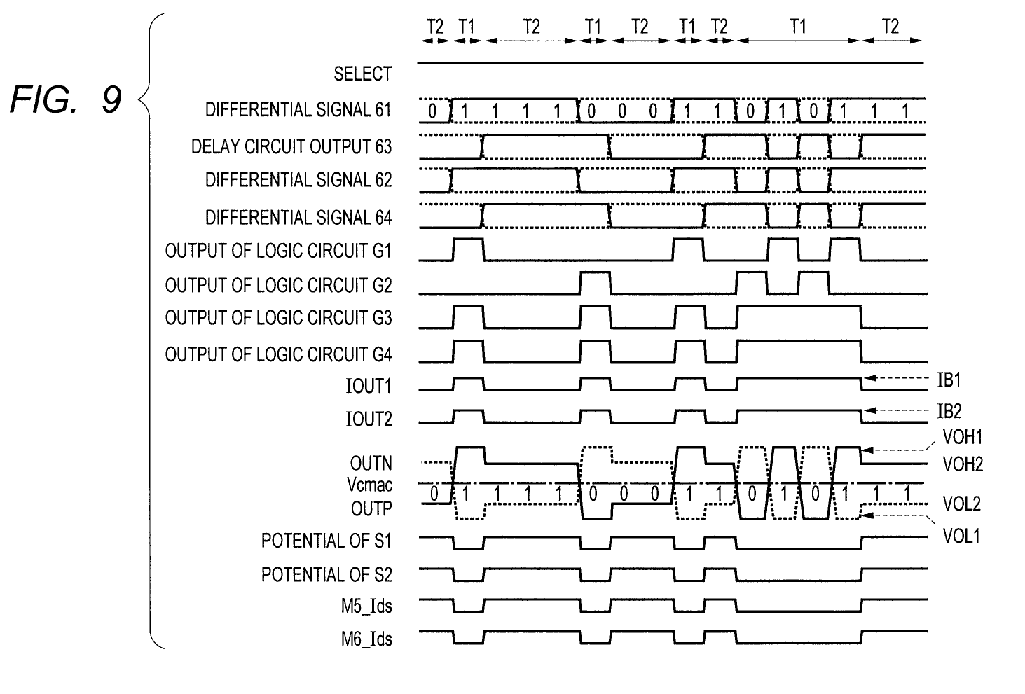

Next, an operation of the output buffer circuit according to the present embodiment is described below with reference to FIG. 9. FIG. 9 is a timing chart illustrating the operation of the buffer circuit according to the present embodiment. In this timing chart, as with FIG. 5, a horizontal axis represents a time, and a vertical axis represents a voltage or a current.

The SELECT signal, the differential signal 61, the differential signal 63 output by the delay circuit 40, the differential signal 62, the differential signal 64, the output of the logic circuit G1 (at node S21), the output of the logic circuit G2 (at node S22), the output of the logic circuit G3 (at node S23), the output of the logic circuit G4 (at node S24), the correction current signal IOUT1, the correction current signal IOUT2, the inverting output OUTN of the output buffer circuit, the non-inverting output OUTP of the output buffer circuit, the potential at the node S1, the potential at the node S2, the drain-source current (M5_Ids) of the N-channel transistor M5, and the drain-source current (M6_Ids) of the N-channel transistor M6 are plotted such that they are shifted in the vertical direction so that no overlapping occurs. In FIG. 9, as in FIG. 5, non-inverting signals of differential signals are represented by solid lines, while inverting signals are represented by dotted lines.

The de-emphasis operation of the output buffer circuit is determined by the logic circuit G4. When the control circuit setting terminal SEL coupled to the logic circuit G4 is at the H level, the de-emphasis operation is enabled and the other input (at the node S23) is directly output at the node S24. On the other hand, when the control circuit setting terminal SEL is at the L level, the de-emphasis operation is disabled the L level is output by the logic circuit G4 whereby the switch 201 and the switch 202 are maintained in the off-state. The signal level at the node S24 indicates the result of the operation performed by the control circuit 203. More specifically, the H-level is output only during the period T1, while the L-level is output during the period T2.

First, an operation in the transition bit state during the period T1 shown in FIG. 9 is described.

As described above, the low logic output level of the non-inverting output terminal OUTP of the output buffer circuit and the low logic output level of the inverting output terminal OUTN of the output buffer circuit cannot drop to as low a level as VOL1, and thus AC common-mode noise Vcmac starts to increase according to equation (1).

Because the node S24, at which the output of the control circuit 203 is provided, is at the H-level, the N-channel transistors M7 and M8 serving as the switches 201 and the switch 202 turn on. As a result, the correction currents IB1 and IB2 flow out from the correction current output terminals IOUT1 and IOUT2. The correction currents IB1 and IB2 are set so as to compensate for a reduction in the drain-source currents of the N-channel transistors M5 and M6.

Thus, in the operation of the main buffer 111 for main data and the main buffer 112 for de-emphasis, the low logic output levels are corrected by the correction currents IB1 and IB2 such that VOL1 is output as the low logic level.

Next, an operation in the non-transition bit state during the period T2 (non-transition bit period) is described. As described above, the low logic output level of the non-inverting output terminal OUTP of the output buffer circuit and the low logic output level of the inverting output terminal OUTN of the output buffer circuit drop to VOL2 higher than VOL1, and thus no reduction occurs in the drain-source current (M5_Ids) of the N-channel transistor M5 and the drain-source current (M6_Ids) of the N-channel transistor M6. Therefore, the AC common-mode noise Vcmac is 0 according to equation (1).

As described above, the current correction circuit 50 provided in the output buffer circuit having the de-emphasis function compensates for the reduction in the currents flowing through the constant current source transistors M5 and M6 that can occur when the low-level signal with the large amplitude is output at the output terminal OUTN or OUTP during the transition bit period, whereby it becomes possible to suppress the AC common-mode noise Vcmac.

That is, only during the transition bit period in which AC common-mode noise Vcmac can occur, the correction current is passed via the switch coupled in parallel to the constant current of the main buffer 11 to make it possible for the low logic output levels of the output terminals OUTP and OUTN of the output buffer circuit to drop to as low a level as VOL1 thereby suppressing the AC common-mode noise Vcmac in this period. Thus, the AC common-mode noise is suppressed.

More specifically, for example, when the high logic output level of the non-inverting output terminal OUTP of the output buffer circuit is 1V and the low logic output level of the inverting output terminal OUTN of the output buffer circuit is −0.8 V, if the voltage determined by the correction current output by the current correction circuit 50 is set to −0.2 V that is added to be the low logic output level of the inverting output terminal OUTN of the output buffer circuit, then Vcmac is calculated as Vcmac=(1 V+(−0.8 V−0.2 V))/2=0 V according to equation (1). Thus no AC common-mode noise occurs.

As described above, in the output buffer circuit according to the first embodiment, the de-emphasis function is achieved without generating AC common-mode noise Vcmac.

Furthermore, the correction current output by the current correction circuit 50 allows the voltage amplitude to have a correct value during the transition bit period, which prevents a reduction in the de-emphasis strength.

### Second Embodiment

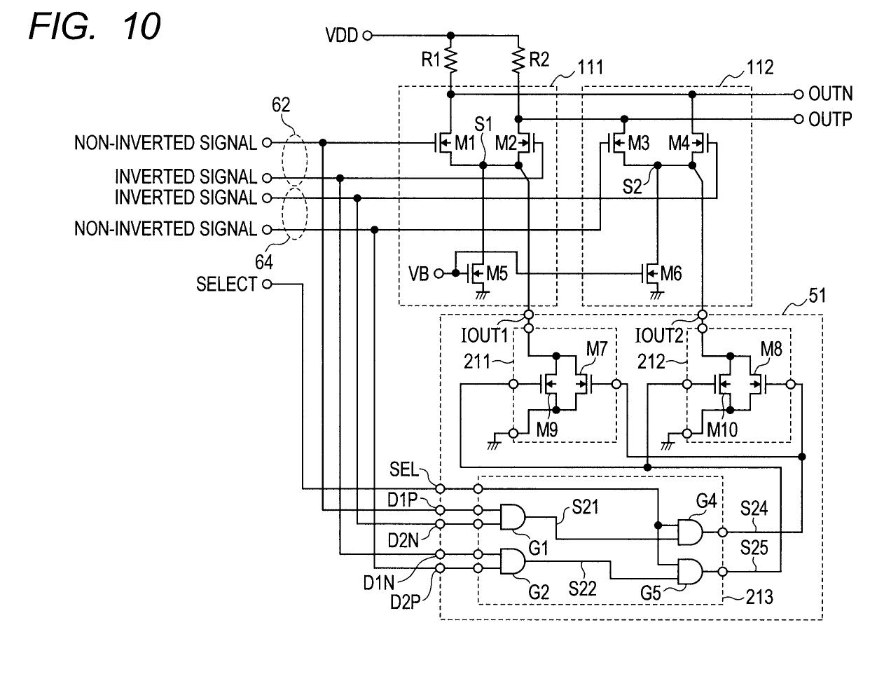

A second embodiment of the present invention is described below with reference to drawings. FIG. 10 is a circuit diagram of a main buffer circuit according to the second embodiment. In FIG. 10, similar elements to those in FIG. 8 are denoted by similar reference numerals and an explanation thereof is omitted.

The second embodiment is different from the first embodiment in that N-channel transistors M9 and M10 are added to the switch 211 and the switch 212, respectively, and the logic circuit G3 is removed from the control circuit 213 and a logic circuit G5 is added to the control circuit 213.

In the switch 211, a drain terminal and a source terminal of the N-channel transistor M9 are respectively coupled to the drain terminal and the source terminal of the N-channel transistor M7, while a gate terminal of the N-channel transistor M9 is coupled to an output of the logic circuit G5. In the switch 212, the N-channel transistor M10 is coupled in a similar manner.

In the control circuit 213, the control circuit setting terminal SEL is input to the logic circuit G4. The other input of the logic circuit G4 is coupled to the output of the logic circuit G1. The output of the logic circuit G4 is coupled to the node S24. The control circuit setting terminal SEL is also input to the logic circuit G5, and the other input of the logic circuit G5 is coupled to the output of the logic circuit G2. The output of the logic circuit G5 is coupled to the node S25.

In the second embodiment, low-speed OR logic circuits are eliminated to reduce the delay time from the input to the output, and the control circuit 213 is configured using only AND logic circuits that can operate at a higher speed. Furthermore, two output signals indicating the operation result are provided by the control circuit 213, and the switch 211 and the switch 212 are each configured in a parallel form. Thus, it becomes possible to handle a higher-speed input signal.

That is, depending on the operation result of the control circuit 213 output from the nodes S24 and S25, the N-channel transistors M7 to M10 of the switch 211 and the switch 212 turn on, which causes the correction currents IB1 and IB2 to flow out from the correction current output terminals IOUT1 and IOUT2. Furthermore, the delay time of the control circuit 203, and the switches 201 and 202 are each configured in a parallel form. Furthermore, the logic circuit G1 functions as a first logic gate that detects a transition of the logic of the input signal from signals input via the main data non-inverting input terminal D1P and the de-emphasis data inverting input terminal D2N. The logic circuit G2 functions as a second logic gate that detects a transition of the logic of the input signal from signals input via the main data inverting input terminal D1N and the de-emphasis data non-inverting input terminal D2P. In this configuration, when either one of the first logic gate and the second logic gate detects a transition in the logic of the signal, N-channel transistors configured in the parallel form in the switch 211 and the switch 212 turn on, and thus it becomes possible to achieve a quicker operation in response to a transition in the logic of the input signal.

Other than the above, the operation is similar to that of the output buffer circuit according to the first embodiment described above.

### Third Embodiment

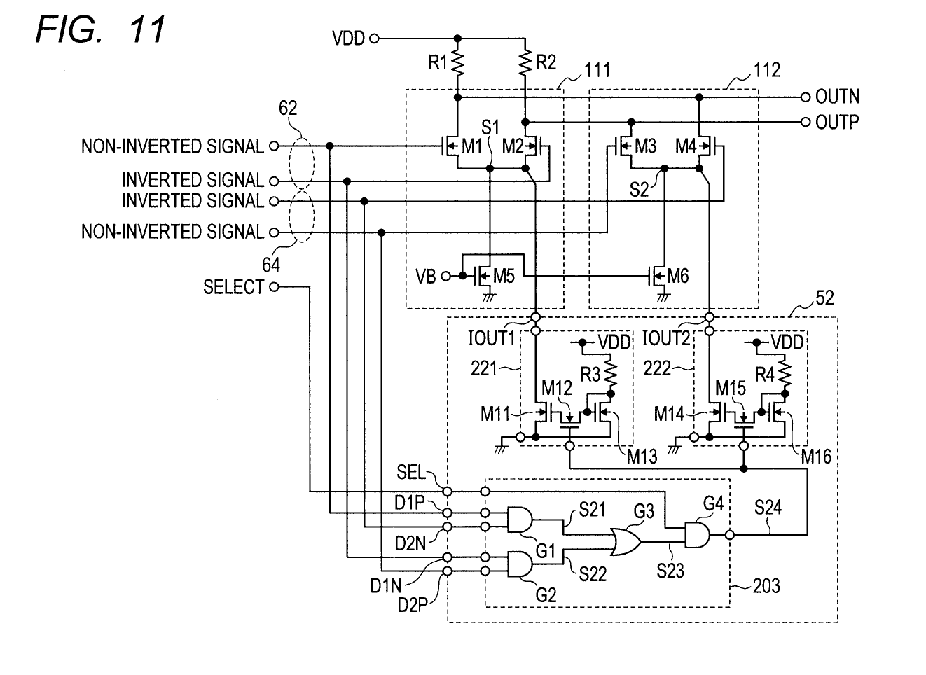

A third embodiment of the present invention is described below with reference to drawings. FIG. 11 is a circuit diagram of a main buffer circuit according to the third embodiment. In FIG. 11, similar elements to those in FIG. 8 are denoted by similar reference numerals and an explanation thereof is omitted.

The second embodiment is different from the first embodiment in that N-channel transistors M7 and M8 are removed from the switch 221 and the switch 222, respectively, and N-channel transistors M11 to M16 and resistors R3 and R4 are added.

In the switch 221, one end of the resistor R3 is coupled to the power supply VDD, and the other end is coupled to the drain terminal and the gate terminal of the N-channel transistor M13 and the drain terminal of the N-channel transistor M12. The source terminal of the N-channel transistor M13 is coupled to the ground. The gate terminal of the N-channel transistor M12 is coupled to the output of the logic circuit G4, while the source terminal is coupled to the gate terminal of the N-channel transistor M11. The drain terminal of the N-channel transistor M11 is coupled to the correction current output terminal IOUT1, while the source terminal is coupled to the ground. The switch 222 is configured in a similar manner.

In the third embodiment, the switch 221 and the switch 222 are configured such that each of them functions as a constant current source whereby an improvement in accuracy of the correction current 65 is achieved. Depending on the result of the operation of the control circuit 203 provided via the node S24, the N-channel transistor M12 in the switch 221 turns on. In response, a current mirror circuit is formed by the resistor R3 and the N-channel transistor M13, which causes a high-precision current to be passed through the N-channel transistor M11, and thus the correction current IB1 flows out from the correction current output terminal IOUT1. The switch 222 operates in a similar manner.

As described above, the provision of the current mirror circuit in each of the switch 221 and the switch 222 makes it possible to perform a high-precision current correction.

Other than the above, the operation is similar to that of the output buffer circuit according to the first embodiment described above.

### Fourth Embodiment

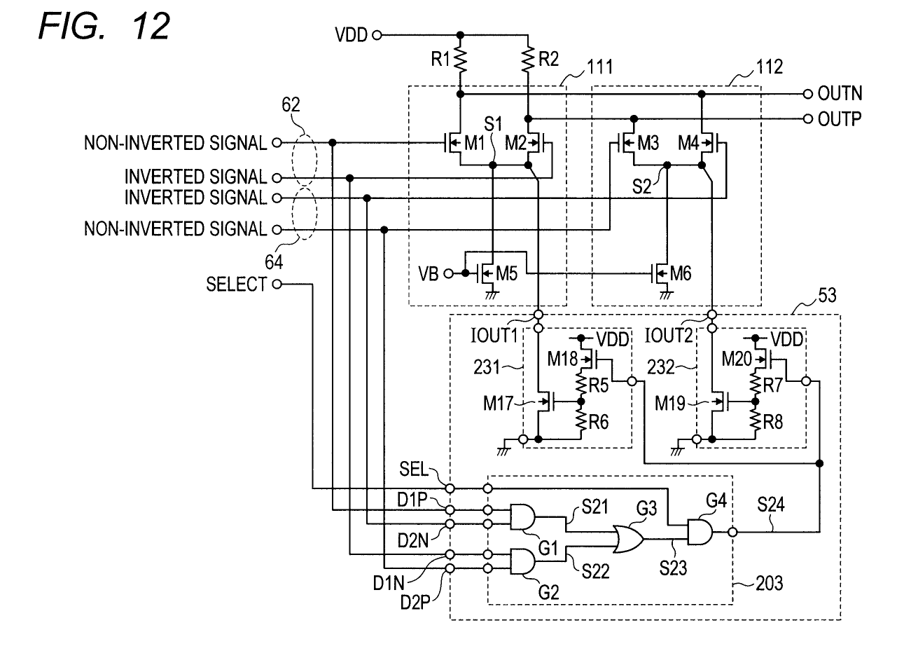

A fourth embodiment of the present invention is described below with reference to drawings. FIG. 12 is a circuit diagram of a main buffer circuit according to the fourth embodiment. In FIG. 12, similar elements to those in FIG. 8 are denoted by similar reference numerals and an explanation thereof is omitted.

The second embodiment is different from the first embodiment in that N-channel transistors M7 and M8 are removed from the switch 231 and the switch 232, respectively, and N-channel transistors M17 to M20 and resistors R5 to R8 are added.

In the switch 231, the N-channel transistor M18 is coupled such that the drain terminal is coupled to the power supply VDD, the gate terminal is coupled to the output of the logic circuit G4, and the source terminal is coupled to one end of the resistor R5. The resistors R5 and R6 are coupled in series, and the node at which the resistors R5 and R6 are coupled to each other is coupled to the gate terminal of the N-channel transistor M17. The other end of the resistor R6 is coupled to the ground. The drain terminal of the N-channel transistor M17 is coupled to the correction current output terminal IOUT1, and the source terminal is coupled to the ground. The switch 232 is configured in a similar manner.

In the fourth embodiment, the switch 231 is configured using the N-channel transistor M17 and a source follower amplifier, and the voltage amplitude is adjusted by a level shift of the result of the operation of the control circuit 203 and a resistance division ratio. This makes it possible to perform a fine adjustment of the correction current 65.

Depending on the result of the operation of the control circuit 203 provided via the node S24, the N-channel transistor M18 in the switch 231 turns on, and a voltage signal level-shifted by an amount corresponding to the gate-source voltage Vgs is output from the source terminal and is further divided by the resistors R5 and R6. Therefore, the voltage amplitude can be adjusted by adjusting the ratio of the resistors R5 and R6.

Thus, the voltage produced by level-shifting the operation result at the node S24 and further performing the adjustment of the voltage amplitude is applied as the gate signal to the N-channel transistor M17, and the N-channel transistor M17 turns on in response to the applied gate signal. As a result, the correction current IB1 flows out from the correction current output terminal IOUT1. That is, the gate voltage of the N-channel transistor M17 can be arbitrarily adjusted by adjusting the resistance division ratio thereby finely adjusting the correction current IB1. The switch 232 operates in a similar manner.

In the present embodiment, as described above, the provision of the N-channel transistor M17 and the source follower amplifier in the switch 231 makes it possible to perform a fine adjustment on the correction current 65.

Other than the above, the operation is similar to that of the output buffer circuit according to the first embodiment described above.

### Fifth Embodiment

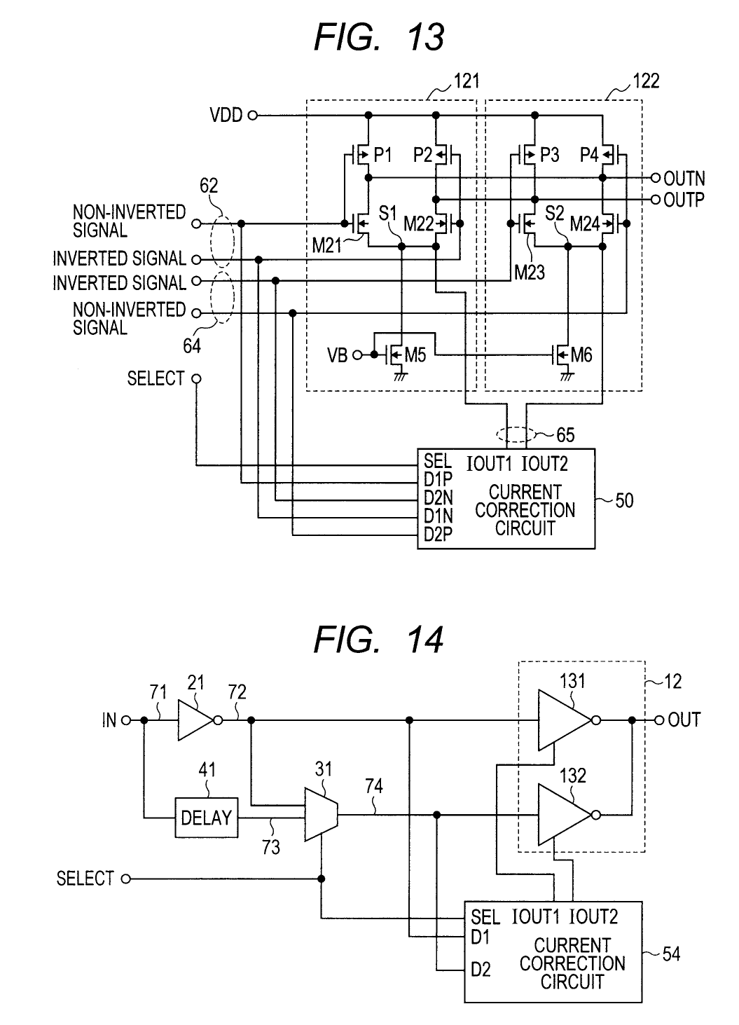

In the first to fourth embodiments described above, the output buffer circuit has the main buffer circuit configured using the load resistors R1 and R2 and the N-channel transistor. In a fifth embodiment, instead, the main buffer circuit is formed using a CMOS (Complementary Metal Oxide Semiconductor) configuration. FIG. 13 is a circuit diagram illustrating a main buffer realized using the CMOS configuration.

The output buffer circuit according to the present embodiment is different from that according to the first embodiment in that the main buffer 111 for main data and the main buffer 112 for de-emphasis are respectively replaced by a main buffer 121 for main data and a main buffer 122 for de-emphasis.

The main buffer 121 for main data includes P-channel transistors P1 and P2, N-channel transistors M21 and M22, and an N-channel transistor M5 functioning as a constant current source. A drain terminal of the P-channel transistor P1 and a drain terminal of the N-channel transistor M21 are coupled together to a node functioning as an inverting output terminal OUTN of the output buffer circuit. Furthermore, a drain terminal of the P-channel transistor P2 and a drain terminal of the N-channel transistor M22 are coupled together to a node functioning as a no-inverting output terminal OUTP of the output buffer circuit. A source terminal of the N-channel transistor M21 and a source terminal of the N-channel transistor M22 are coupled to a drain terminal of the N-channel transistor M5. The non-inverting signal of the differential signal 62 is coupled to a gate terminal of the P-channel transistor P1 and a gate terminal of the N-channel transistor M21, while the inverting signal of the differential signal 62 is coupled to a gate terminal of the P-channel transistor P2 and a gate terminal of the N-channel transistor M22. The main buffer 122 for de-emphasis is configured in a similar manner.

Also in the case where the main buffer 121 for main data and the main buffer 122 for de-emphasis are formed using the CMOS configurations, it is necessary to output a signal with a large amplitude in the de-emphasis-enabled state in which the amplitude is emphasized, and thus a reduction can occur in the drain-source voltage Vds of the N-channel transistors M5 and M6 functioning as constant current sources, which leads to a reduction in the constant currents I1 and I2. Therefore, also in this configuration, the low logic output level of the non-inverting output terminal OUTP of the output buffer circuit and the low logic output level of the inverting output terminal OUTN of the output buffer circuit cannot drop to as low a level as VOL1, and thus AC common-mode noise Vcmac starts to increase according to equation (1), and a reduction in de-emphasis strength occurs.

In view of the above, a current correction circuit similar to one of the current correction circuits 50 to 53 according to the first to fourth embodiments is used to compensate for the reduction in currents flowing through the constant current source transistors M5 and M6 thereby suppressing the AC common-mode noise Vcmac and thus preventing the reduction in the de-emphasis strength.

Note that in the configuration shown in FIG. 13, by way of example, the current correction circuit 50 is employed as the current correction circuit. The main buffer 121 for main data, the main buffer 122 for de-emphasis, and the current correction circuit (any one of the current correction circuits 50 to 53) operate in a similar manner as in the first to fourth embodiments, and thus a duplicated description is omitted.

### Sixth Embodiment

In the first to fifth embodiments described above, the output buffer circuit is configured to handle a differential signal. The output buffer circuit may be configured to have a de-emphasis function and have a capability of handling a single-ended signal. Also in this case in which the output buffer circuit is configured to handle a single-ended signal, it is necessary to output a signal with a large amplitude to emphasize the amplitude in the de-emphasis-enabled state, and thus a reduction can occur in the drain-source voltage Vds of N-channel transistors functioning as constant current sources, and a reduction can occur in de-emphasis strength. In view of the above, a sixth embodiment provides an output buffer circuit capable of handing a single-ended signal.

FIG. 14 is a block diagram of an output buffer circuit having a de-emphasis function for a single-ended signal. The output buffer circuit shown in FIG. 14 includes a main buffer 12, an inverter 21, a selection circuit 31, a delay circuit 41, and a current correction circuit 54. The main buffer 12 includes a main buffer 131 for main data and a main buffer 132 for de-emphasis.

Input data applied to the output buffer circuit is given in the form of a single-ended signal 71 at an input terminal IN. The inverter 21 receives the single-ended signal 71 as an input thereto and outputs a single-ended signal 72 produced by inverting the input single-ended signal 71.

The delay circuit 41 receives the single-ended signal 71 as an input thereto and outputs a single-ended signal 73 produced by delaying the input single-ended signal 71.

The selection circuit 31 selects either the single-ended signal 72 or the single-ended signal 73 and outputs the selected signal as a single-ended signal 74.

The main buffer 131 for main data receives the single-ended signal 72 as an input thereto, while the main buffer 132 for de-emphasis receives the single-ended signal 74 as an input thereto. The output of the main buffer 131 for main data and the output of the main buffer 132 for de-emphasis are coupled together to a node functioning as an output terminal OUT such that a signal produced by inverting each input signal is output from the output terminal OUT.

The single-ended signal 72 is coupled to a D1 terminal of the current correction circuit 54. The single-ended signal 74 is coupled to a D2 terminal of the current correction circuit 54. A de-emphasis setting terminal SELECT is coupled to a control circuit setting terminal SEL. A terminal IOUT1 of the current correction circuit 54 is coupled to the main buffer 131 for main data, while a terminal IOUT2 of the current correction circuit 54 is coupled to the main buffer 132 for de-emphasis.

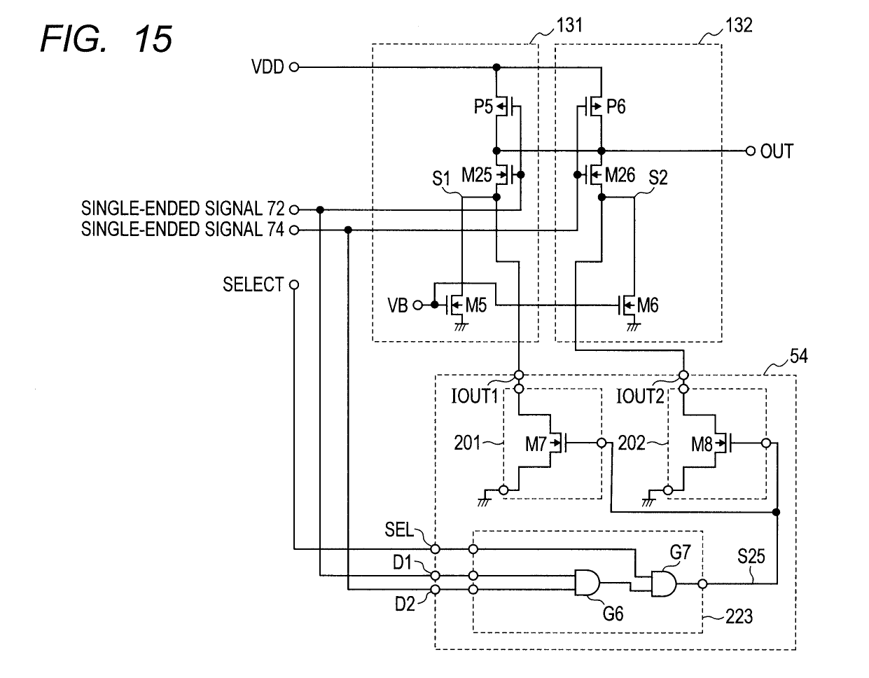

FIG. 15 is a circuit diagram of the main buffer 12 and the current correction circuit 54. The main buffer 131 for main data includes a P-channel transistor P5, an N-channel transistor M25, and an N-channel transistor M5 functioning as a constant current source. A drain terminal of the P-channel transistor P5 and a drain terminal of the N-channel transistor M25 are coupled together to a node functioning as an output terminal OUT. Furthermore, a source terminal of the P-channel transistor P5 is coupled to a power supply VDD, and a source terminal of the N-channel transistor M25 is coupled to a drain terminal of the N-channel transistor M5. A source terminal of the N-channel transistor M25 is coupled to IOUT1 of the current correction circuit 54. Furthermore, the single-ended signal 72 is coupled in common to a gate terminal of the P-channel transistor P5 and a gate terminal of the N-channel transistor M25. The main buffer 132 for de-emphasis is configured in a similar manner to the main buffer 131 for main data.

Next, an operation of the output buffer circuit capable of handling the single-ended signal is described below for a case where the de-emphasis is enabled. The de-emphasis operation for the single-ended signal is similar to that for the differential signal. That is, in the de-emphasis-enabled state, emphasis is made on the amplitude of a first bit immediately after a transition occurs in the logic of the output signal. That is, in the de-emphasis-enabled state, the main buffer 12 subtracts the single-ended signal 73 delayed by the delay circuit 41 from the single-ended signal 72 and outputs a signal having an amplitude emphasized at a transition in the logic of the signal.

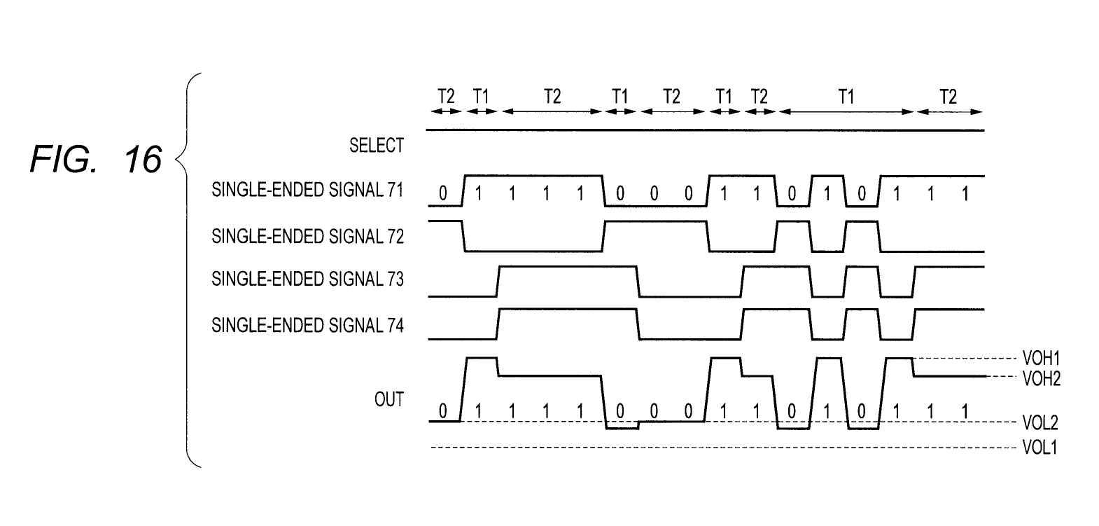

As described above, in the output buffer circuit capable of handling the single-ended signal, the de-emphasis function is realized by emphasizing a bit immediately after a transition in logic level of the signal. However, also for the single-ended signal, it is necessary to output a signal with a large amplitude to emphasize the amplitude in the de-emphasis-enabled state, which brings about a problem that a reduction can occur in the drain-source voltage Vds of N-channel transistors functioning as constant current sources, and the low logic output level of the output terminal OUT of the output buffer circuit cannot drop to as low a level as VOL1 (see FIG. 16).

To solve the above problem, a current correction circuit is used to correct a current that flows through the constant current source in the de-emphasis-enabled state. Although the current correction circuit 54 according to the present embodiment is different from the current correction circuit 50 according to the first embodiment in that the control circuit 203 is configured differently, the basic operation is similar to that of the current correction circuit 50 according to the first embodiment. That is, the de-emphasis is enabled when the control circuit setting terminal SEL is at the H level. In the de-emphasis-enabled state, immediately after a transition in the input signal from 0 to 1 (during a transition bit period), the output of the AND logic circuit G6 goes to the H level, and this H level signal is directly output by the AND logic circuit G7 from the node S25 thereby turning on the switches 201 and 202, which makes it possible for the current correction circuit 54 to compensate for the reduction in the currents flowing through the constant current source transistors M5 and M6. Thus, it becomes possible for the low logic output level of the output terminal OUT of the output buffer circuit to drop to as low a level as VOL1. Note that the switches 201 and 202 in the current correction circuit 54 may be replaced by the switches 221 and 222 or the switches 231 and 232. However, the switches 211 and 212 are designed to be used to handle differential signals, and thus the switches 211 and 212 cannot be used instead of the switches 201 and 202.

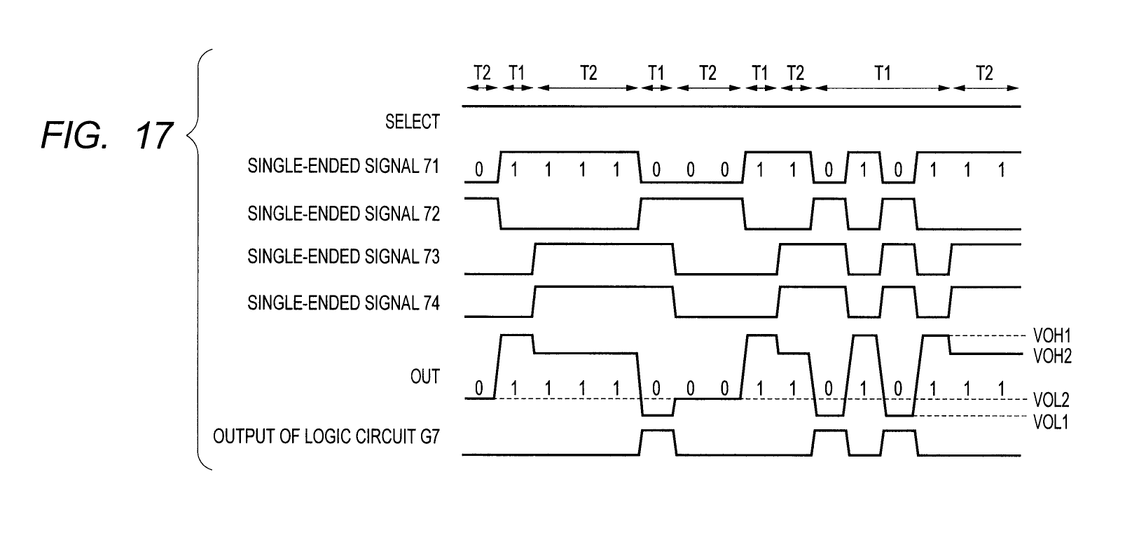

FIG. 17 illustrates operating waveforms in the state in which the de-emphasis is enabled for a single-ended signal. In the operation described above with reference to FIG. 16, the low logic output level does not drop to as low a level as VOL1. In contrast, in the operation shown in FIG. 17, the currents flowing through the N-channel transistors M5 and M6 are corrected by the current correction circuit 54 thereby making it possible for the low logic output level to drop to as low a level as VOL1.

Thus, the provision of the current correction circuit 54 makes it possible to prevent a reduction in the de-emphasis strength given by the voltage amplitude ratio between the transition bit period and the non-transition bit period.

Note that the disclosure of patent documents, etc., cited above is incorporated herein by reference in its entirety. Various modifications and adjustments are possible without departing from the basic technical spirit and the scope of the disclosure (including claims) of the invention. A wide variety of combinations or selections of elements disclosed may be possible without departing from the scope of the present invention as defined in claims. That is, it should be understood that various modifications and changes that are apparent to those skilled in the art fall into the scope of the present invention. For example, N-channel transistors and P-channel transistors may be replaced with each other, if additional changes in terms of coupling of the power supply or the like are properly performed. That is, N-channel transistors may be employed as transistors of the first conductivity type, while P-channel transistors may be employed as transistors of the second conductivity type.

What is claimed is:

1. An output buffer circuit comprising:
a first buffer circuit configured to receive an input signal;
a second buffer circuit configured to receive a signal produced by delaying the input signal and configured to be coupled to the same output terminal as that to which the first buffer circuit is coupled to, so as to output an output signal that is delayed and inversed in phase with respect to an output signal output by the first buffer circuit; and
a current correction circuit configured to correct source currents flowing through the first and second buffer circuits when a transition occurs in the logic of the input signal.

2. The output buffer circuit according to claim 1,
wherein the first and second buffer circuits each include a current source circuit, and
wherein the current correction circuit controls the source currents so as to compensate for reductions in the currents flowing through the current source circuits when a transition occurs in the logic of the input signal.

3. The output buffer circuit according to claim 2,
wherein the current correction circuit includes:
a plurality of switches that are coupled in parallel to the respective current source circuits and that are capable of supplying currents in parallel to the respective current source circuits; and
a control unit configured to detect the transition in the logic of the input signal and turn on/off the switches.

4. The output buffer circuit according to claim 3, wherein each of the switches includes a MOS transistor coupled such that a source and a drain thereof are coupled in parallel to the corresponding current source circuit and a gate thereof is coupled to an output signal of the control unit.

5. The output buffer circuit according to claim 3, wherein each of the switches includes:
a current mirror circuit, and
a MOS transistor coupled to the current mirror circuit, whereby a current is supplied or shut off via the MOS transistor.

6. The output buffer circuit according to claim 3, wherein each of the switches includes
a source follower amplifier that is controlled by the control unit,
a series of resistors coupled to the source follower amplifier, and
a MOS transistor coupled such that a gate thereof is coupled to a middle node of the series of resistors and a source and a drain thereof are coupled in parallel to the corresponding one of the current source circuits.

7. The output buffer circuit according to claim 4,
wherein the control unit includes:
a first AND circuit configured to output a logical AND between a non-inverting signal of the input signal and an inverting signal of a delayed input signal;
a second AND circuit configured to output a logical AND between an inverting signal of the input signal and a non-inverting signal of the delayed input signal; and
an OR circuit configured to output a logical OR between the output of the first AND circuit and the output of the second AND circuit, and
wherein the control unit controls turning-on/off of the switches according to a logical AND between the output of the OR circuit and a selection signal.

8. The output buffer circuit according to claim 1,
wherein the output terminal is a pair of differential signal output terminals,
wherein the first and second buffer circuits are each a differential circuit configured to receive a pair of differential signals and output a pair of differential signal to the pair of differential signal output terminals,
wherein a non-inverting signal output terminal of the first buffer circuit is coupled to an inverting signal output terminal of the second buffer circuit, and an inverting signal output terminal of the first buffer circuit is coupled to a non-inverting signal output terminal of the second buffer circuit, and
wherein the current correction circuit corrects a current passed through the differential pair such that a common-mode voltage at the pair of differential signal output terminals is maintained constant.

9. The output buffer circuit according to claim 8,
wherein the differential pair includes:
a first transistor of a first conductivity type; and
a second transistor of the first conductivity type, and
wherein the output buffer circuit further comprises:
a third transistor of a second conductivity type which is coupled between the first transistor and a power supply, an input signal being coupled in common to the first transistor and the third transistor; and
a fourth transistor of the second conductivity type which is coupled between the second transistor and the power supply, an input signal being coupled in common to the second transistor and the fourth transistor.

10. The output buffer circuit according to claim 8,
wherein the control unit includes a first logic gate configured to detect a first transition in a logic of the input signal, and a second logic gate configured to detect a second transition in the logic of the input signal, and
wherein each of the switches includes a first switch and a second switch configured such that the first switch is coupled in parallel to the current source circuit and the turning-on/off of the first switch is controlled by the first logic gate, and the second switch is coupled in parallel to the current source circuit and the first switch and the turning-on/off of the second switch is controlled by the second logic gate.

11. The output buffer circuit according to claim 1, wherein the first buffer circuit and the second buffer circuit handle a single-ended signal given as an input.

12. The output buffer circuit according to claim 1, further comprising:
a load circuit coupled to the output terminal,
wherein the voltage at the output terminal is determined by a current flowing through the load circuit.

13. A semiconductor device including an output buffer circuit according to claim 1.
